(19) United States
(12) Patent Application Publication
(10) Pub. No.: US 2025/0069920 A1
(43) Pub. Date: Feb. 27, 2025

(54) LOAD LOCK ARRANGEMENTS, SEMICONDUCTOR PROCESSING SYSTEMS INCLUDING LOAD LOCK ARRANGEMENTS, AND ASSOCIATED METHODS FOR REGULATING THE TEMPERATURE OF SUBSTRATES WITHIN LOAD LOCK ARRANGEMENTS

(71) Applicant: ASM IP Holding B.V., Almere (NL)

(72) Inventors: Masaei Suwada, Nagaoka-shi (JP); Taira Okabe, Kawasaki-shi (JP)

(21) Appl. No.: 18/806,906

(22) Filed: Aug. 16, 2024

Related U.S. Application Data
(60) Provisional application No. 63/578,434, filed on Aug. 24, 2023.

(51) Int. Cl. H01L 21/67

(52) U.S. Cl. CPC H01L 21/67201; H01L 21/67248

(57) ABSTRACT

Load lock assemblies, semiconductor processing systems including load lock assemblies, and associated methods for regulating the temperature of a substrate within load lock assemblies are disclosed. The load lock assemblies include a temperature control assembly coupled to an elevator, the elevator configured to provide vertical movement to the temperature control assembly within a load lock body.

### CROSS-REFERENCE TO RELATED APPLICATION(S)

This application claims the benefit of U.S. Provisional Application 63/578,434 filed on Aug. 24, 2023, the entire contents of which are incorporated herein by reference.

### FIELD

The present disclosure relates generally to the field of semiconductor processing systems and methods, and to the field of device and integrated circuit manufacture. More particularly, the present disclosure relates to load lock arrangements, semiconductor processing system including load lock arrangements, and methods for regulating the temperature of substrates within load lock arrangements.

### BACKGROUND

Semiconductor processing systems, such as those employing cluster-type platforms, commonly include a front-end connected to a back-end by a load lock arrangement. The front-end generally interfaces the semiconductor processing system to the external environment and typically includes a front-end substrate transfer robot to transfer substrates between the front-end module and the load lock arrangement. The back-end typically includes one or more process modules wherein the substrate processing is performed, as well as a back-end substrate transfer chamber including a back-end substrate transfer robot employed to transfer substrates between the load lock arrangement and the process modules. The load lock arrangement generally couples the back-end of the semiconductor processing system to the front-end of the semiconductor processing system and is typically arranged to isolate the environment maintained in the back-end of the semiconductor processing system from the environment maintained in the front-end of the semiconductor processing system.

Substrates transferred from a process module to the load lock arrangement are commonly received and seated within the load lock arrangement at an elevated temperature due to the various substrate processes performed within the process module and the need to free-up the process modules to process further substrates. Such heated substrates can be cooled prior to transfer from the load lock arrangement to the front-end of the semiconductor processing system. Alternatively, substrates seated within the load lock arrangement which are to undergo processing in a process module can be pre-heated prior to transfer to the process module as a way to reduce the time to reach process temperature in the process module.

However, an extended time period of substrate cooling/heating within the load lock arrangement can negatively impact the rate of substrates processed within the semiconductor processing system. In addition, since the load lock arrangement commonly has a front face that interfaces with the front-end of the semiconductor processing apparatus and a rear face that interfaces with the back-end of the semiconductor processing apparatus, additional interfacing to the load lock arrangement can be complex due to restricted access and/or limited space within and in proximity of the load lock arrangement. Accordingly, improved load lock arrangements and semiconductor processing systems including such load lock arrangements and are desirable, as well as methods for regulating the temperature of substrates within the load arrangements.

Any discussion, including discussion of problems and solutions, set forth in this section has been included in this disclosure solely for the purpose of providing a context for the present disclosure. Such discussion should not be taken as an admission that any or all of the invention was previously known or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to load lock arrangements. As set forth in more detail below, the load lock arrangements described herein can be used during the manufacture of electronic devices. Such load lock arrangements can reduce complexity and/or cost of manufacturing devices.

In accordance with examples of the disclosure, a load lock arrangement is provided. In such examples the load lock arrangement includes a load lock body that includes a front face configured for coupling with an equipment front-end module, a rear face configured for coupling with a back-end transfer module, and a side face including a side aperture. In such examples, a substrate stage is disposed within the load lock body, the substrate stage including an upper stage surface and a lower stage surface. In such examples, the upper stage surface is configured for retaining a substrate at a retaining location within the load lock body. In such examples, a temperature control assembly is partially disposed within the load lock body, and an elevator is coupled to the temperature control assembly for providing vertical movement to the temperature control assembly. In such examples, a flexible sealing mechanism is connected between the side face of the load lock body and the temperature control assembly, the flexible sealing mechanism maintaining an environment within the load lock body while moving the temperature control assembly.

In accordance with examples of the disclosure, the load lock arrangement may also include, where the side aperture has a first cross-sectional dimension greater than the maximum cross-section dimension of the temperature control assembly such that the temperature control assembly is inserted and extracted through the side aperture.

In accordance with examples of the disclosure, the lock arrangement can also include where the temperature control assembly includes a temperature regulating head having an upper temperature regulating surface.

In accordance with examples of the disclosure, the load lock arrangement can also include where the elevator is configured for positioning the upper temperature regulating surface at a distance of greater than 10 mm from the lower stage surface when unloading/loading a substrate from/into the load lock arrangement.

In accordance with examples of the disclosure, the lock arrangement may also include where the substrate stage includes a secondary stage for retaining an addition substrate.

In accordance with examples of the disclosure, the load lock arrangement can also include where the load lock body further includes an upper load lock chamber and a lower load lock chamber, the temperature control assembly being partially disposed within the upper load lock chamber.

In accordance with examples of the disclosure, the load lock arrangement may also further include a sealing plate connected to the side face of the load lock body, the sealing plate including a sealing aperture that is aligned with the side aperture, the sealing aperture having a second cross-sectional dimension less than the first cross-sectional dimension.

In accordance with examples of the disclosure, the load lock arrangement may also include where the flexible sealing mechanism includes a bellows.

In accordance with examples of the disclosure, the load lock arrangement may also include where a first end of the bellows has a third cross-sectional dimension greater than the first cross-sectional dimension such that the first end of the bellows contacts a sealing surface of the sealing plate and encloses the sealing aperture forming a first gas tight seal.

In accordance with examples of the disclosure, the load lock arrangement may also include where a second end of the bellows contacts a sealing surface of the temperature control assembly forming a second gas tight seal.

In accordance with examples of the disclosure, the load lock arrangement may also include where the sealing surface of the temperature control assembly includes a surface of a flange of the temperature control assembly.

In accordance with examples of the disclosure, the lock arrangement may also include where the elevator provides a maximum vertical displacement to the upper temperature regulating surface of between 1 mm and 15 mm.

In accordance with examples of the disclosure, the lock arrangement may also include where the elevator is configured for positioning the upper temperature regulating surface at a distance of less than 0.5 mm from the lower stage surface when regulating the temperature of a substrate seated on the upper stage surface.

In accordance with examples of the disclosure, the load lock arrange may also include an additional temperature control assembly partially disposed within the lower load lock chamber and coupled to a lower elevator for providing vertical displacement to the additional temperature control assembly.

Various further embodiments of the present disclosure relate to semiconductor processing systems including load lock arrangements. As set forth in more detail below, the semiconductor processing systems described herein can be used during the manufacture of electronic devices. Such load lock arrangements can reduce complexity and/or cost of manufacturing devices.

In one aspect, a semiconductor processing system includes a load lock arrangement including a load lock body, a substrate stage housed within the load lock body, and a temperature control assembly including at a proximal end a temperature regulating head located within the load lock body and at a distal end a coupling connected to an elevator for raising and lowering the temperature regulating head, the distal end extending laterally through a side aperture located in a side face of the load lock body such that the distal end is located outside of the load lock body. In such examples, the semiconductor processing system can further include a flexible sealing mechanism connected between the side face of the load lock body and the temperature control assembly, the flexible sealing mechanism maintaining an environment within the load lock body during the movement of the temperature regulating head. In such examples, the semiconductor processing system can further include a back-end transfer module connected to a rear face of the load lock body, the back-end transfer module coupling a process module to the load lock arrangement. In such examples, the semiconductor process system can further include an equipment front-end module connected to a front face of the load lock body, the equipment front-end module housing a front-end substrate transfer robot. In such examples, the elevator is configured for lowering the temperature regulating head to allow the front-end substrate transfer robot to load/unload a substrate and raises the temperature regulating head to position the temperature regulating head proximate to the substrate stage to provide at least one of heating and cooling to a substrate seated on the substrate stage.

In accordance with examples of the disclosure, the semiconductor processing apparatus may also include where the load lock body further includes an upper load lock chamber and a lower load lock chamber, the temperature control assembly being partially disposed within the upper load lock chamber. Other technical features may be readily apparent to one skilled in the art from the following figures, descriptions, and claims.

In accordance with examples of the disclosure, the semiconductor processing apparatus may further include an additional temperature control assembly partially disposed within the lower load lock chamber and coupled to a lower elevator for providing vertical displacement to the additional temperature control assembly. Other technical features may be readily apparent to one skilled in the art from the following figures, descriptions, and claims.

Various further embodiments of the present disclosure relate to methods for regulating the temperature of a substrate within a load lock arrangement. As set forth in more detail below, the methods described herein can be used during the manufacture of electronic devices. Such methods can reduce complexity and/or cost of manufacturing devices.

In one aspect, a method of regulating the temperature of a substrate within a load lock arrangement includes, at a load lock body housing a substrate stage, the substrate stage including an upper stage surface and a lower stage surface, the upper stage surface configured for retaining a substrate at a retaining location within the load lock body. In such examples the method can further include lowering a vertical position of a temperature control assembly partially disposed within the load lock body to a load/unload position, the unload/load position being distal from the lower stage surface. In such examples the method can further include seating a process substrate on the upper stage surface at the retaining location, and raising the vertical position of the temperature control assembly to a substrate temperature regulating position proximate to the lower stage surface to enable at least one of heating and cooling to the substrate positioned at the retaining location, where lowering and raising of the temperature control assembly is implemented by an elevator coupled to a distal portion of the temperature control assembly extending outside of the load lock body through an aperture located in a side face of the load lock body.

In accordance with examples of the disclosure, methods may also include where the temperature control assembly includes a temperature regulating head having an upper temperature regulating surface, where the upper temperature regulating surface is positioned at a distance greater than 10 mm from the lower stage surface when in the loading/unloading position.

In accordance with examples of the disclosure, the method may also include where the upper temperature regulating surface is positioned at a distance less than 0.5 mm from the lower stage surface when in the substrate temperature regulating position. Other technical features may be readily apparent to one skilled in the art from the following figures, descriptions, and claims.

These and other embodiments will become readily apparent to those skilled in the art from the following detailed description of certain embodiments having reference to the attached figures. The invention is not limited to any particular embodiments disclosed.

### BRIEF DESCRIPTION OF DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates a semiconductor processing system in accordance with one or more embodiments of the disclosure.

FIG. 2 illustrates a load lock arrangement in accordance with one or more embodiments of the disclosure.

FIG. 3 illustrates a further load lock arrangement in accordance with one or more embodiments of the disclosure.

FIG. 4 illustrates an additional load lock arrangement in accordance with one or more embodiments of the disclosure.

FIG. 5 illustrates a temperature control assembly in accordance with one or more embodiments of the disclosure.

FIG. 6 illustrates an additional load lock arrangement in accordance with one or more embodiments of the disclosure.

FIG. 7 illustrates a further load lock arrangement in accordance with one or more embodiments of the disclosure.

FIG. 8 illustrates an additional load lock arrangement including an upper load lock chamber and a lower load lock chamber in accordance with one or more embodiments of the disclosure.

FIG. 9 illustrates a method of regulating a temperature of a substrate disposed within a load lock arrangement in accordance with one or more embodiments of the disclosure.

### DETAILED DESCRIPTION

The description of exemplary embodiments of apparatus, assemblies and methods provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As set forth in more detail below, various embodiments of the present disclosure relate to load lock arrangements, semiconductor processing systems including load lock arrangements, and associated methods for regulating the temperature of a substrate within a load lock arrangement. As set forth in more detail, the load lock arrangements described herein can be used during the manufacture of electronic devices. Such load lock arrangements can reduce the complexity and/or cost of manufacturing devices/integrated circuits, and increase the throughput of substrates processed within a semiconductor processing apparatus. In addition, the load lock arrangements and associated semiconductor processing systems and methods disclosed within can increase the accessibility and functionality of such apparatus, systems, and methods.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide, for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

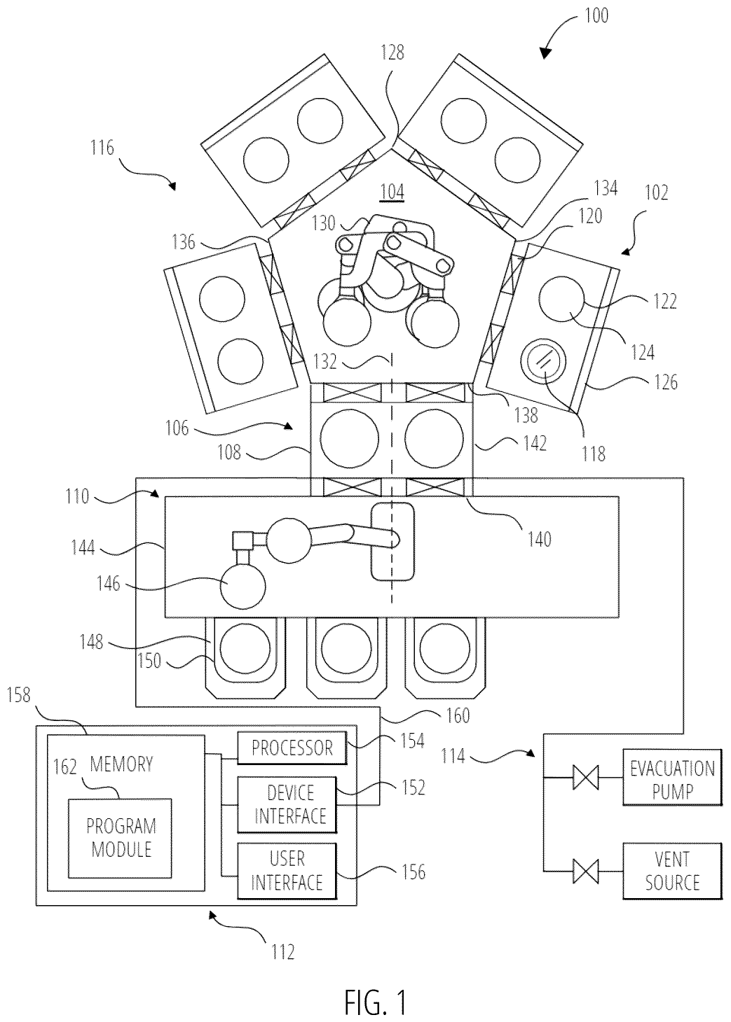

Turning now to the figures, FIG. 1 illustrates a semiconductor processing system 100. The semiconductor processing system 100 includes a process module 102, a back-end transfer module 104, and a load lock arrangement 106 including load lock body 108. The semiconductor processing system 100 also includes an equipment front-end module (EFEM) 110, a controller 112, and an evacuation/venting source 114. In the illustrated example the semiconductor processing system 100 includes a cluster-type platform 116 with four (4) process modules configured to deposit a material layer onto a substrate 118 using a deposition technique, such as, atomic layer deposition (ALD), chemical vapor deposition (CVD), plasma-enhanced chemical vapor deposition (PECVD), and plasma-enhanced atomic layer deposition (PEALD), for example. This is for illustration and description purposes only and is non-limiting. As will be appreciated by those of skill in the art in view of the present disclosure, semiconductor processing systems configured for other material layer deposition operations as well as semiconductor processing systems configured for processing operations other than material layer deposition can also benefit from the present disclosure.

The process module 102 is coupled to the back-end transfer module 104 by a process module gate valve 120. The process module 102 includes a process chamber 122, a heater 124, and a reactant source 126. The process chamber 122 is arranged within the process module 102, houses the heater 124, and is configured to flow a precursor or reactant across the substrate 118 while seated on the heater 124 during deposition of a material layer onto the substrate 118. The precursor/reactant source 126 is fluidly coupled to the process chamber 122 and configured to provide the precursor/reactant to the process chamber 122 for deposition of the one or more material layers onto the substrate 118. The process module gate valve 120 couples the process module 102 to the back-end transfer module 104 and is configured to provide selective communication between the process chamber 122 and the back-end transfer module 104. In this respect it is contemplated that the process module gate valve 120 can be configured to permit transfer of the substrate 118 between the back-end transfer module 104 and the process module 102 before and after deposition of material layer(s) onto the substrate 118.

In accordance with examples of the disclosure, the process chamber 122 may be a first process chamber and the process module 102 may include one or more second process chambers. For example, the process module 102 may be a dual chamber module having two (2) process chambers or a quad chamber module having four (4) process chambers. In accordance with certain examples, the process module gate valve 120 may be a first process module gate valve and the process module 102 may include a second process module gate valve also coupling the process module 102 to the back-end transfer module 104. It is contemplated that, in certain examples, the reactant may include a reactant or a precursor suitable for deposition of a material layer, such as using an atomic layer deposition, or a chemical vapor deposition technique. It is also contemplated that, in accordance with certain examples, the process module 102 includes a plasma unit configured to provide the reactant 126 to the substrate 118 as a suitable plasma. In this respect the process module 102 may be configured to deposit a material layer onto the substrate 118 using a plasma-enhanced atomic layer deposition or a plasma-enhanced chemical vapor deposition technique by way of example.

The back-end transfer module 104 is coupled to a rear face 138 of the load lock body 108 and includes a back-end chamber body 128 and a back-end substrate transfer robot 130. The back-end chamber body 128 is arranged along a transfer axis 132. It is contemplated that the back-end substrate transfer robot 130 be arranged within an interior of the back-end chamber body 128 and supported within the back-end chamber body 128 for movement relative to the back-end chamber body 128 for transfer of substrates, e.g., the substrate 118, between the load lock arrangement 106 and the process module 102. In certain examples, the back-end chamber body 128 may have a polygonal shape. In this respect the back-end chamber body 128 may have five sides, fewer than five sides (e.g., a rectangular or square shape), or more than five sides (e.g., a hexagonal shape), and may have the shape of a regular polygon or an irregular polygon.

The equipment front-end module (EFEM) 110 is coupled to a front face 140 of the load lock body 108 and includes an enclosure 144, a front-end substrate transfer robot 146, and one or more load port 148. The enclosure 144 houses the front-end substrate transfer robot 146. The front-end substrate transfer robot 146 is housed within the enclosure 144 for movement relative to the enclosure 144 or transfer of substrates, e.g., the substrate 118, between the one or more load ports 148 and the load lock arrangement 106. The one or more load ports 148 are connected to the enclosure 144 and are configured to seat therein a pod 150 housing one or more substrates, prior to and subsequent to deposition of material layers onto the substrates. In certain examples, the pod 150 may include a standard mechanical interface pod. In accordance with certain examples, the pod 150 may include a front-opening unified pod. Although shown and described herein as having three (3) load ports it is to be understood and appreciated that equipment front-end module 110 may include fewer or additional load ports and remain within the scope of the present disclosure.

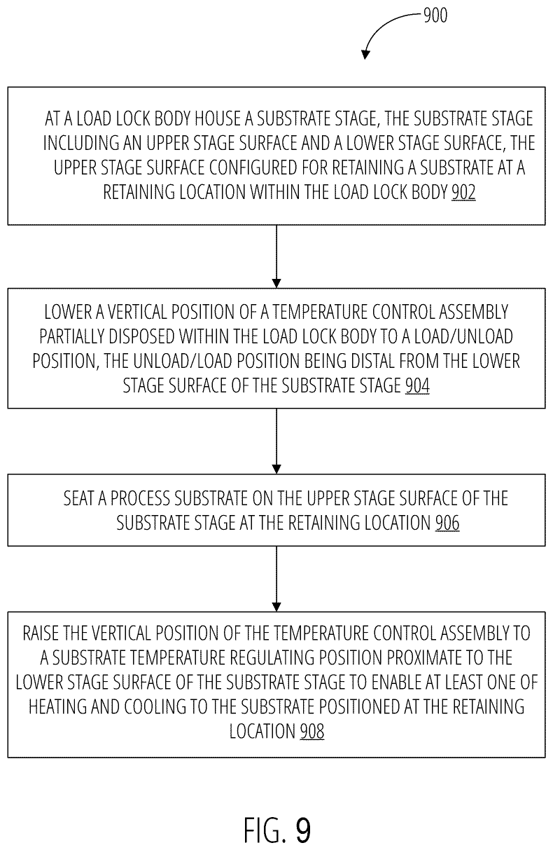

The controller 112 is operably connected to the semiconductor processing system 100 and includes a device interface 152, a processor 154, a user interface 156, and a memory 158. The device interface 152 couples the processor 154 to the semiconductor processing system 100, for example, through (or over) a wired or wireless link 160. The processor 154 is operably connected to the user interface 156 and is disposed in communication with the memory 158. The memory 158 includes a non-transitory machine-readable medium having a plurality of program module 162 recorded thereon containing instructions that, when read by the processor 154, cause the processor 154 to execute certain operations. Among the operations are operations for regulating a temperature of substrate within the load lock arrangement 106 as illustrated by method 900 (shown in FIG. 9), as will be described below.

As has been explained above, some semiconductor processing systems can include substrate heating and/or substrate cooling within the load lock arrangement 106, such as for throughput purposes. For example, in some semiconductor processing systems, substrate heating within the load lock arrangement can be implemented to limit processing time within the process module to shortening the time taken to ramp the substrate temperature to a desired material layer deposition temperature. Alternatively, or additionally, substrate cooling within the load lock arrangement 106 may be implemented to limit processing time within the process modules. To meet the requirements for substrate cooling and/or substrate heating, as well as to meet the need for a load lock arrangement with increased flexibility, accessibility and configuration, the load lock arrangement 106 is provided.

As illustrated in FIG. 1 the load lock arrangement 106 includes a front face 140 configured (i.e., constructed and arranged) for coupling with an equipment front-end module 110, a rear face 138 configured (i.e., constructed and arranged) for coupling with a back-end transfer module, and a side face 142 constructed and arranged for insertion of a temperature control assembly, as will be described below. In addition, the load lock arrangement 106, and particularly the load lock body 108 can include an upper load lock chamber, a lower load lock chamber, as will be described in detail below.

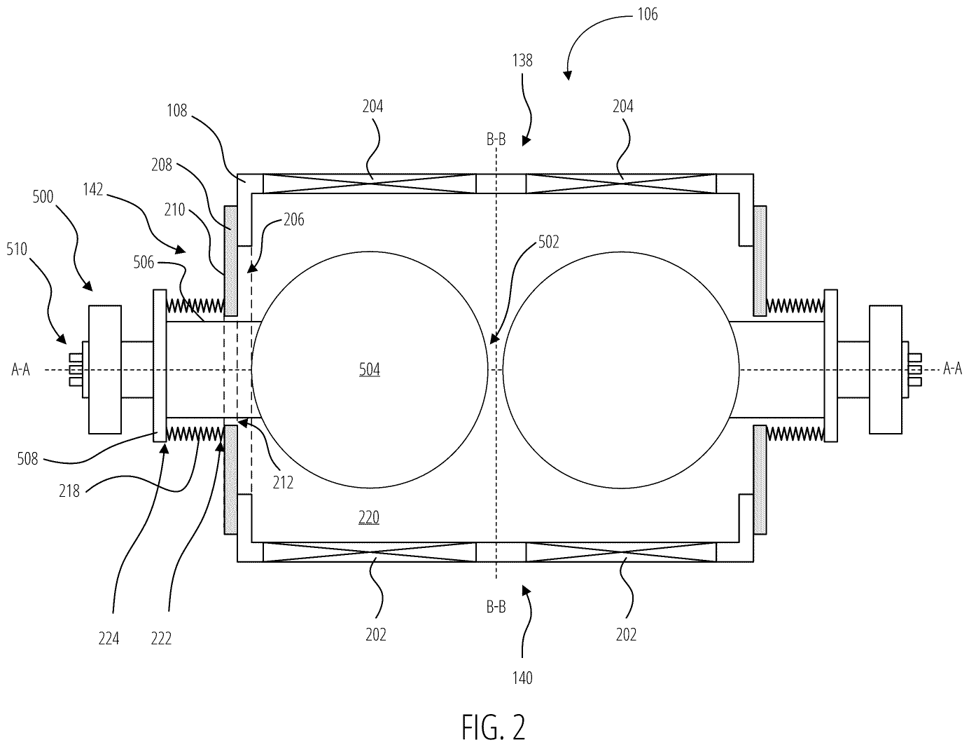

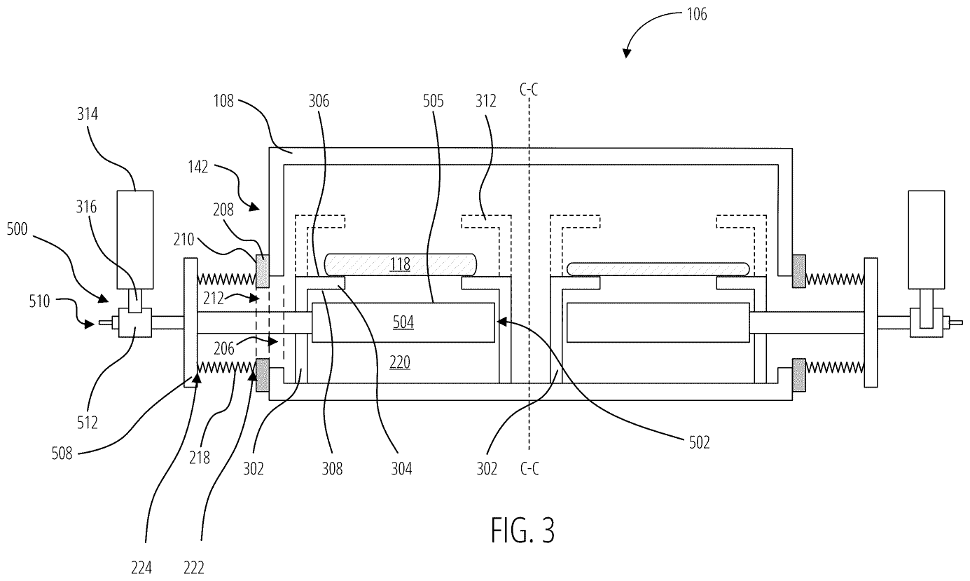

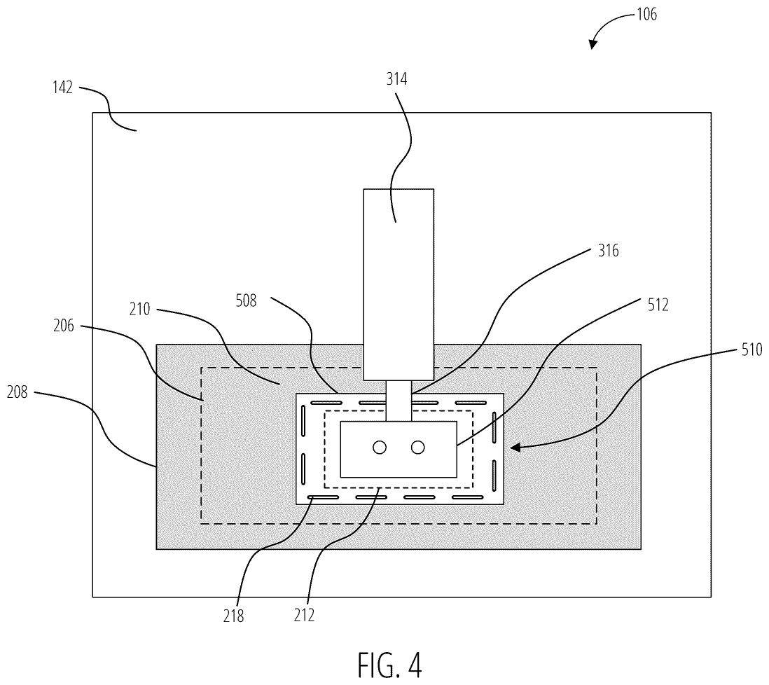

FIG. 2, FIG. 3, and FIG. 4 illustrate different views of an exemplary load lock arrangement 106 in accordance with examples of the disclosure. FIG. 2 is a cut-away top down illustration of the internal configuration of the load lock elements within the load lock arrangement, FIG. 3 is cross-sectional view looking along line A-A of FIG. 2, and FIG. 3 illustrates a side face 142 of the load lock body 108 and the configuration of the load lock elements. The following detailed includes reference to FIG. 2, FIG. 3, and FIG. 4 and common elements are commonly labelled. In addition, the exemplary illustrations of load lock arrangement 106 in FIG. 2 and FIG. 3 are substantially symmetrical about axis B-B (FIG. 2) and about axis C-C (FIG. 3), and therefore the detailed description of the load lock arrangement 106 illustrated in FIG. 2 and FIG. 3 focuses on the load lock elements to the left of axis B-B and axis C-C and those element right of axis B-B and axis C-C are assumed to be the same, unless otherwise stated.

In more detail, the load lock arrangements 106 of the present disclosure includes a load lock body 108. The load lock body 108 includes a front face 140 configured for coupling with an equipment front-end module, as illustrated in FIG. 2. The front face 140 includes one or more front gate valves 202 for allowing controllable transfer of substrates through the front face 140 of the load lock body 108 to a front-end module whilst maintaining an environment with the load lock body 108. The load lock body 108 also includes a rear face 138 configured for coupling with a back-end transfer module. The rear face 138 includes rear gate valves 204 for allowing controllable transfer of substrates through the rear face 138 of the load lock body 108 to a back-end substrate transfer robot. The load lock body 108 also includes side faces, such as the side face 142. The side face 142 includes a side aperture 206 which extends through the load lock body 108, the side aperture 206 having a first cross-sectional dimension such that select load lock elements can be inserted and extracted through the side aperture 206 into and out of the load lock body 108 (illustrated in FIGS. 2-4). In some examples of the disclosure, a sealing plate 208 can be attached to the side face 142, the sealing plate 208 including a sealing surface 210, and a sealing aperture 212 which extends through the sealing plate 208. In such examples, the sealing aperture 212 is aligned with the side aperture 212. In such examples, the sealing aperture 212 can have a second cross-sectional dimension less than the first cross-sectional dimension of the side aperture 206 (illustrated in FIGS. 2-4).

In accordance with examples of the disclosure, a substrate stage 302 is disposed within the load lock body 108 (as illustrated in FIG. 3). The substrate stage 302 encompasses support element 304 having an upper stage surface 306 and a lower stage surface 308. The upper stage surface 306 is configured for a retaining a substrate 118 at a retaining location within the load lock body 108. In some aspects, the upper stage surface 306 can include multiple raised elements, and/or one or more recessed features for retaining the substrate 118 at a fixed position whilst seated on the upper stage surface 306 of the substrate stage 302. As illustrated in FIG. 3, the load lock body 108 can house two substrate stages 302 including a single level for retaining a substrate. In further examples of the disclosure, the substrate stage 302 can optionally include an upper substrate stage 312 (illustrated as a dashed line to indicate this element is optional) for a retaining an addition substrate at the retaining location within the load lock body 108. In such examples, the optional upper substrate stage 312 can be located directly above the substrate stage 302 (i.e., the lower substrate stage). In accordance with examples of the disclosure, a singular substrate stage can include both the substrate stage 302 (i.e., the lower substrate stage) and the upper substrate stage 312.

The load lock arrangements of the disclosure further include one or more temperature control assemblies. The temperature control assemblies are employed for the heating and/or cooling of substrates disposed within the load lock body. For example, substrate heating within the load lock arrangements of the present disclosure can be employed to shorten processing time within a process module by reducing the time required to ramp the substrate temperature to a desired process temperature. Alternatively, or additionally, substrate cooling within the load lock arrangements of the present disclosure can be employed to limit processing time within the process modules by allowing cooling outside of process modules, thereby freeing up the process modules and allowing processing of additional substrates and increasing substrate throughput through the semiconductor process system.

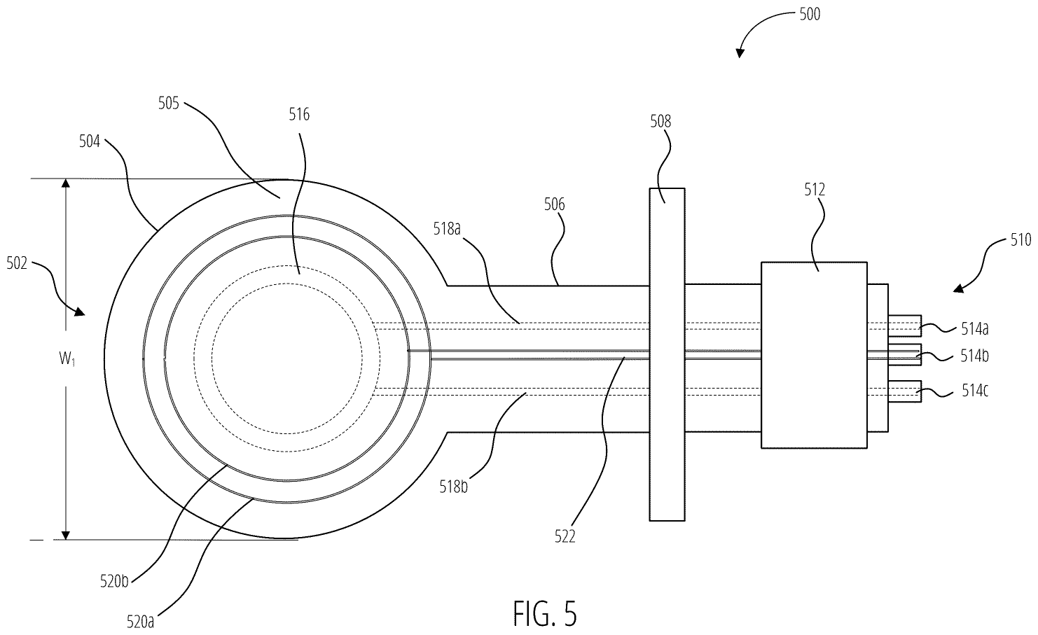

In more detail, FIG. 5 illustrates a temperature control assembly 500 in accordance with examples of the disclosure. The temperature control assembly 500 includes a proximal end 502 including a temperature regulating head 504 including an upper temperature regulating surface 505. In some embodiments, the temperature control assembly 500 and particularly the temperature regulating head 504 can have a maximum width W₁. In accordance with examples of the disclosure, the temperature regulating head 504 can include cooling and/or heating mechanisms, as described below. The temperature control assembly 500 also includes a neck section 506 connected to the temperature regulating head 504, and a flange 508 connected to the neck section 506. The temperature control assembly 500 includes a distal end 510 including a coupling 512 for connecting the temperature control assembly 500 to an elevator, the elevator providing vertical movement to the temperature control assembly 500 and particularly to the temperature regulating head 504. In some embodiments, the distal end 510 further includes ports 514a, 514b, and 514c, for providing cooling and/or heating to the temperature regulating head 504. In accordance with examples of the disclosure, the temperature regulating head 504 is configured to convey heating and/or cooling to a substrate 118 retained on the upper stage surface 306 of the substrate stage 302 (as illustrated in FIG. 3).

In accordance with examples of the disclosure, the temperature regulating head 504 includes a cooling mechanism (as illustrated in FIG. 5). In such cases, the cooling mechanism can include one or more sealed channels through which a cooling fluid can be introduced and withdrawn. In accordance with examples of the disclosure, a cooling channel 516 is fed with a coolant from feed channels 518a and 518b via ports 514a and 514c. In such examples, the feed channels 518a and 518b extend through the neck section 506, and the flange 508 of the temperature control assembly 500, forming fluidic conduits between the temperature regulating head 504 and the distal end 510 of the temperature control assembly 500. The cooling channel 516, the feed channels 518a and 518b, are illustrated by dashed lines to signify they are disposed within the temperature control assembly 500, although it is anticipated that other configurations for the cooling channel and the feed channels can be incorporated into temperature control mechanism 500. In accordance with examples of the disclosure, the cooling channel 516, can be supplied with a cooling fluid through port 514a, and the cooling fluid can be extracted from the cooling channel 516 through port 514c. In some embodiments, ports 514a and 514c can be fluidly connected to a chiller system to provide a temperature controlled fluid to the temperature regulating head 504.

In accordance with further examples of the disclosure, the temperature regulating head 504 alternatively or additionally includes a heating mechanism. In such examples, the heating mechanism can include heating elements disposed within and/or on the temperature regulating head 504, such as elements 520a and 520b. The heating elements can include resistive heating elements which are electrically connected via conductive lines 522 which extend through the neck section 506, the flange 508, through to the port 514b at the distal end 510 of the temperature control assembly 500, where external electrical connections can be made for powering the heating element within the temperature regulating head 504.

FIGS. 2-4 illustrate the configuration of the temperature control assembly 500 with respect to the load lock arrangements 106 of the present disclosure. In accordance with examples of the disclosure, the load lock arrangements 106 of the present disclosure can include a temperature control assembly 500 partially disposed within the load lock body 108, as illustrated in FIG. 2 and FIG. 3. In some embodiments, the proximal end 502 of the temperature control assembly 500 includes the temperature regulating head 504. In accordance with examples of the disclosure, the temperature regulating head 504 is disposed within the load lock body 108. In such examples, the temperature regulating head 504 is located below the support element 304 such that an upper temperature regulating surface 505 of the temperature regulating head 504 is substantially parallel to the lower stage surface 308 of the substrate stage 302 (as illustrated in FIG. 3). In addition, a center of the upper temperature regulating surface 505 of the temperature control assembly 500 is aligned with the retaining location at which a substrate 118 is supported on the upper stage surface 306 of the substrate stage 302.

In accordance with examples of the disclosure, the distal end 510 of the temperature control assembly 500 extends laterally through the side aperture 206 located in the side face 142 of the load lock body 108 such that the distal end 510 is located outside of the load lock body 108. In some embodiments, the distal end 510 of the temperature control assembly 510 extends laterally through the sealing aperture 212 of the sealing plate 208. In some embodiments, the side aperture 206 and the sealing aperture 212 are aligned such that the distal end 510 of the temperature control assembly extends laterally through both the side aperture 206 and the sealing aperture 212.

In accordance with examples of the disclosure, the distal end 510 of the temperature control assembly 500 further includes a coupling 512. The coupling 512 is connected to an elevator 314 (see FIG. 3) thereby coupling the elevator 314 to the temperature control assembly 500, the elevator 314 providing vertical movement to the temperature control assembly 500 and as a consequence provides vertical movement to the temperature regulating head 504. Therefore, the elevator 314 permits the raising and lowering of the temperature regulating head 504 within the load lock body 108. In accordance with examples of the disclosure, the elevator 314 can further comprise an elevator arm 316, the elevator arm 316 being moveable in a substantially vertical direction to provide vertical movement to the temperature regulating head 504 of the temperature control assembly 500.

In accordance with examples of the disclosure, the load lock arrangements of the present disclosure further include a flexible sealing mechanism. In some embodiments of the disclosure and with reference to FIG. 2 and FIG. 3, a flexible sealing mechanism 218 can be connected between the side face 142 of the load lock body 108 and the temperature control assembly 500, the flexible sealing mechanism 218 maintaining an environment within the load lock assembly 220 while moving (i.e., vertically displacing) the temperature control assembly 500, and particular maintaining the environment within the load lock body while lowering and raising the temperature regulating head 504 of the temperature control assembly 500, in relation to the lower stage surface 308 of the substrate stage 304.

In accordance with examples of the disclosure, the flexible sealing mechanism 218 can comprise a bellows. In such examples, the bellows can comprise an edge welded metal bellows including a plurality of diaphragm plates connected to form a bellows core, the bellows core being connected at either end by welded end fittings to complete the bellows assembly. In such examples, the bellows core is sealed at either end by the end fittings which are in turn sealed to the load lock assembly (e.g., at the side face 142 and the temperature control assembly 500) to maintain the environment within the load lock body as the bellows moves, e.g., as the bellows compresses and expands during movement up and down of the temperature regulating head 504 of the temperature control assembly 500.

In some embodiments of the disclosure, a first end of the bellows 222 has a third cross-sectional dimension greater than a second cross-sectional dimension of the sealing aperture 212 of the sealing plate 208 such that the first end of the bellows 222 contacts the sealing surface 210 of the sealing plate 208 and encloses the sealing aperture 212. A gas tight seal is thereby formed between the first end of the bellows 222 and the sealing surface 210 of the sealing plate 208.

In some embodiments of the disclosure, the second end of the bellows 224 is connected to a sealing surface of the temperature control assembly 500 and encloses the temperature control assembly 500. In such examples, the sealing surface of the temperature control assembly 500 can comprises a surface of the flange 508 of the temperature control assembly. In such examples, the sealing surface of the temperature control assembly can include the surface of the flange 508 facing the sealing plate 208. A gas tight seal is thereby formed between the second end of the bellows 224 and a sealing surface of the flange 508. In other examples, the sealing surface of the temperature control assembly 500 can include a surface of the neck section 506 and gas tight seal is thereby formed between the second end of the bellows 224 and a sealing surface of the neck section 506 of the temperature control assembly 500.

To further illustrate the flexible sealing of the temperature control assembly to the load lock chamber body to enable vertical movement of the temperature control assembly whilst maintaining the internal atmosphere with the load chamber body, FIG. 4 illustrates a side view of the load lock arrangements of the present disclosure.

In greater detail, the side view of the load lock arrangements 106 includes the side face 142 of the load lock chamber 108. The side face 142 of the load lock body 108 includes the side aperture 206, the side aperture 206 extending through the side face 142 of the load lock body 108. The side aperture 206 is illustrated as a dashed line as it concealed by the sealing plate 208. In accordance with examples of the disclosure, the side aperture 206 has a first cross-sectional dimension greater than the maximum cross-sectional dimension (W₁) of the temperature control assembly 500 such that, prior to installing the sealing plate 208, the temperature control assembly can be inserted and extracted through the side aperture 206.

In accordance with examples of the disclosure, the sealing plate 208 is connected to the side face 142 of the load lock body 108, and the sealing plate 208 includes a sealing aperture 212. The sealing aperture 212 again is illustrated as a dashed line as it is concealed by the flange 508 of the temperature control assembly 500 inserted into the side face 142 of the load lock arrangement 106 through the side aperture 206. In such examples, the sealing aperture 212 is aligned with the side aperture 206 disposed in the side face 142 of the load lock body 108. In accordance with examples of the disclosure, the sealing aperture 212 has a second cross sectional dimension less than the first cross-sectional dimension of the side aperture 206. As illustrated in FIG. 4, the distal end 510 of the temperature control assembly 500 extends outside of the load lock body 108 such that the elevator 314 can coupled to the temperature control assembly 500 by means of the elevator arm 316 and the coupling 512. In accordance with examples of the disclosure, the bellows 218 (illustrated here as a dashed line 218 that contacts a surface of the flange 508) forms a gas tight seal with the flange 508 and encloses the sealing aperture 212. In such examples, a first end of the bellows contacts the flange 508 such that third a cross-sectional dimension of the bellows is greater than the second cross-sectional dimension of the sealing aperture 212. In such examples, a first end of the bellows contacts the flange 508 such that a third cross-sectional dimension of the bellows is less than the first cross-sectional dimension of the side aperture 206.

Therefore, in accordance with examples of the disclosure, a first end of the bellows has a third cross-sectional dimension greater than a second cross-sectional dimension of the sealing aperture such that the first end of the bellows contacts a sealing surface of the sealing plate and encloses the sealing aperture. In such examples, a second end of the bellows contacts a sealing surface of the temperature control assembly and encloses the temperature control assembly. In some embodiments, the sealing surface of the temperature control assembly comprises a surface the flange 512 of the temperature control assembly 500.

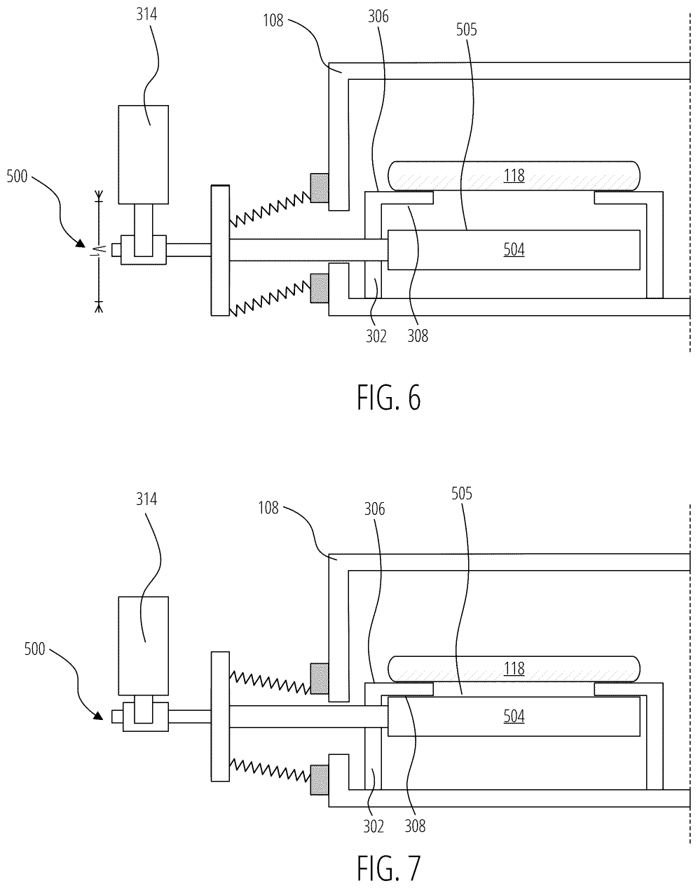

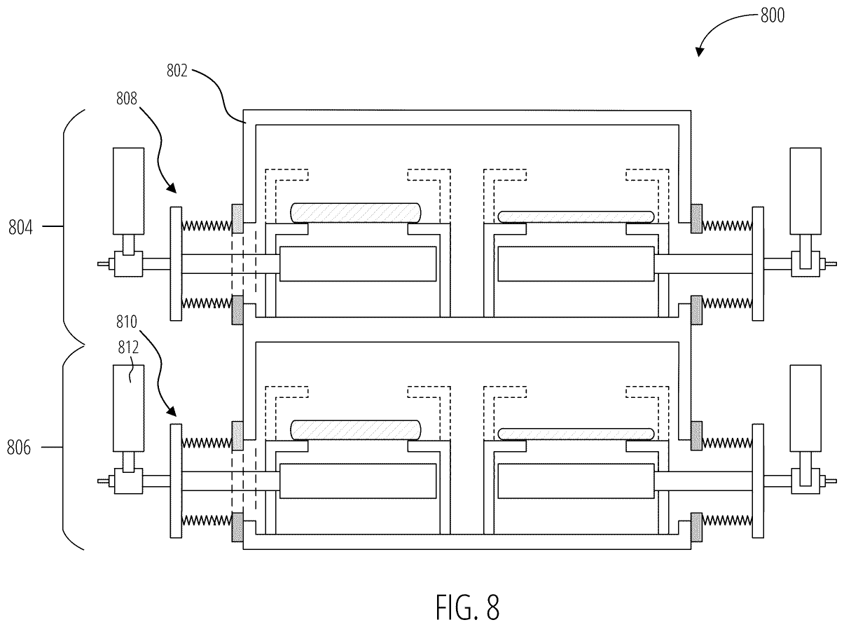

In accordance with examples of the disclosure, the elevator provides vertical movement to the temperature control assembly. FIG. 6 and FIG. 7 further illustrate the vertical movement of the temperature control assembly within the load lock arrangement of the present disclosure.

In accordance with embodiments of the disclosure, the elevator 314 is configured for lowering the temperature regulating head 504 of the temperature control assembly 500 to a load/unload position (as illustrated in FIG. 6), the unload/load position locating the upper temperature regulating surface 505 of the temperature control assembly 500 distal from the lower stage surface 308 of the substrate stage 302. Positioning the temperature control assembly 500 in the unload/load position allows sufficient clearance between the lower stage surface 308 of the substrate stage 302 and the upper temperature regulating surface 505 of the temperature regulating head 504 to allow a front-end substrate transfer robot to load/unload a substrate 118 from/to the load lock body 108.

In particular, in some embodiments, the elevator 314 is configured for raising the temperature regulating head 504 of the temperature control assembly 500 to a temperature regulating position (as illustrated in FIG. 7), the temperature regulating position locating the upper temperature regulating surface 505 of the temperature control assembly 500 proximate to the lower stage surface 308 of the substrate stage 302. Positioning the temperature control assembly 500 in the temperature regulating position allows sufficient proximity between a substrate 118 seated on the upper stage surface 306 of the substrate stage 302 and the upper temperature regulating surface 505 of the temperature regulating head 504 to enable efficient heating and/or cooling to the substrate 118 disposed within the load lock body 108.

In accordance with examples of the disclosure, the elevator 314 provides a maximum vertical displacement (V₁) to the temperature regulating head 504 between 0.5 mm and 20 mm, or between 1 mm and 15 mm, or between 2 mm and 10 mm, or between 3 mm and 8 mm. In some embodiments, the elevator 314 provides a maximum vertical displacement (V₁) to the temperature regulating head 504 greater than 0.5 mm, or greater than 1 mm, or greater than 2 mm, or greater than 3 mm, or greater than 5 mm, or greater than 8 mm, or greater than 10 mm, or greater than 15 mm, or greater than 20 mm.

In accordance further examples of the disclosure, the elevator 314 is configured for positioning the upper temperature regulating surface 505 of the temperature regulating head 504 at a distance of less than 5 mm, or less than 2 mm, or less than 1 mm, or less than 0.9 mm, or less than 0.8 mm, or less than 0.7 mm, or less than 0.6 mm, or less than 0.5 mm from the lower stage surface 308 of the substrate stage 302 when positioning the temperature control assembly 500 in the temperature regulating position. In accordance further examples of the disclosure, the elevator 314 is configured for positioning the upper temperature regulating surface 505 of the temperature regulating head 504 at a distance of between 0.5 mm and 5 mm, or between 0.6 mm and 2 mm, or between 0.7 mm and 1 mm from the lower stage surface 308 of the substrate stage 302 when positioning the temperature control assembly 500 in the temperature regulating position.

In accordance further examples of the disclosure, the elevator 314 is configured for positioning the upper temperature regulating surface 505 of the temperature regulating head 504 at a distance of greater than 5 mm, or greater than 7 mm, or greater 10 mm, or greater 12 mm, or greater than 15 mm from the lower stage surface 308 of the substrate stage 302 when positing the temperature control assembly in the unload/load position. In accordance further examples of the disclosure, the elevator 314 is configured for positioning the upper temperature regulating surface 505 of the temperature regulating head 504 at a distance of between 5 mm and 15 mm, or between 7 mm and 12 mm, or between 8 mm and 10 mm from the lower stage surface 308 of the substrate stage 302 when positioning the temperature control assembly in the unload/load position.

In accordance with further examples of the disclosure, the load lock arrangements of the present disclosure can further include a load lock body including both an upper load lock chamber and a lower load lock chamber. In more detail, FIG. 8 illustrates a load lock arrangement 800 according to the embodiments of the present disclosure. The load lock arrangement 800 includes a load lock body 802 that comprises an upper load lock chamber 804 and a lower load lock chamber 806. In such examples, a temperature control assembly 808 is partially disposed within the upper load lock chamber 804. In such embodiments, the load lock arrangement 800 can further comprise an additional temperature control assembly 810 partially disposed within the lower load lock chamber 806 and coupled to a lower elevator 812 for providing vertical displacement to the additional temperature control assembly 810.

In accordance with further embodiments of the disclosure, FIG. 9 illustrates an exemplary method 900 for regulating the temperature of a substrate disposed within a load lock arrangement of the present disclosure. In more detail, method 900 comprises at a load lock body housing a substrate stage, the substrate stage including an upper stage surface and a lower stage surface, the upper stage surface configured for retaining a substrate at a retaining location within the load lock body (step 902).

In some embodiments of the disclosure method 900 also includes, lowering a vertical position of a temperature control assembly partially disposed within the load lock body to a load/unload position, the unload/load position locating an upper temperature regulating surface of the temperature control assembly distal from the lower stage surface of the substrate stage (step 904).

In some embodiments of the disclosure method 900 also includes, seating a substrate on the upper stage surface of the substrate stage at the retaining location (step 906)

In some embodiments of the disclosure method 900 also includes, raising the vertical position of the temperature control assembly to a substrate temperature regulating position, the substrate temperature regulating position locating an upper temperature regulating surface of the temperature control assembly proximate to the lower stage surface of the substrate stage to enable at least one of heating and cooling to a substrate positioned at the retaining location (step 908).

In some embodiments of the disclosure method 900 also includes, where lowering and raising of the temperature control assembly is implemented by an elevator coupled to a distal portion of the temperature control assembly extending outside of the load lock body through an aperture located in a side face of the load lock body.

In some embodiments of the disclosure, the method 900 also includes wherein the temperature control assembly includes a temperature regulating head having an upper temperature regulating surface, and the upper temperature regulating surface is positioned at a distance greater than 10 mm from the lower stage surface when in the load/unloading position. Further, in some embodiments, the method 900 also include the upper temperature regulating surface is positioned at a distance of less than 0.5 mm from the lower stage surface when located in the substrate temperature regulating position.

Although certain embodiments and examples have been discussed, it will be understood by those skilled in the art that the scope of the claims extend beyond the specifically disclosed embodiments to other alternative embodiments and/or uses and obvious modifications and equivalents thereof. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

In the present disclosure, where conditions and/or structures are not specified, the skilled artisan in the art can readily provide such conditions and/or structures in view of the present disclosure, as a matter of routine experimentation.

1. A load lock arrangement comprising:
a load lock body comprising a front face configured for coupling with an equipment front-end module, a rear face configured for coupling with a back-end transfer module, and a side face including a side aperture;
a substrate stage disposed within the load lock body, the substrate stage including an upper stage surface and a lower stage surface, the upper stage surface configured for retaining a process substrate at a retaining location within the load lock body;
a temperature control assembly partially disposed within the load lock body;
an elevator coupled to the temperature control assembly for providing vertical movement to the temperature control assembly; and
a flexible sealing mechanism connected between the side face of the load lock body and the temperature control assembly, the flexible sealing mechanism maintaining an internal environment within the load lock body while moving the temperature control assembly.

2. The load lock arrangement of claim 1, wherein the side aperture has a first cross-sectional dimension greater than a maximum cross-sectional dimension of the temperature control assembly such that the temperature control assembly is inserted and extracted through the side aperture.

3. The load lock arrangement of claim 2, further comprising a sealing plate connected to the side face, the sealing plate including a sealing aperture that is aligned with the side aperture, the sealing aperture having a second cross-sectional dimension less than the first cross-sectional dimension.

4. The load lock arrangement of claim 3, wherein the flexible sealing mechanism comprising a bellows.

5. The load lock arrangement of claim 4, wherein a first end of the bellows has a third cross-sectional dimension greater than the first cross-sectional dimension such that the first end of the bellows contacts a sealing surface of the sealing plate and encloses the sealing aperture forming a first gas tight seal.

6. The load lock arrangement of claim 5, wherein a second end of the bellows contacts a sealing surface of the temperature control assembly forming a second gas tight seal.

7. The load lock arrangement of claim 6, wherein the sealing surface of the temperature control assembly comprises a surface a flange section of the temperature control assembly.

8. The load lock arrangement of claim 1 wherein the temperature control assembly includes a temperature regulating head.

9. The load lock arrangement of claim 8 wherein the elevator provides a maximum vertical displacement to an upper temperature regulating surface of the temperature regulating head between 1 mm and 15 mm.

10. The load lock arrangement of claim 9 wherein the elevator is configured for positioning the upper temperature regulating surface at a distance of less than 0.5 mm from the lower stage surface when regulating a temperature of a substrate seated on the upper stage surface.

11. The load lock arrangement of claim 10 wherein the elevator is configured for positioning the upper temperature regulating surface at a distance of greater than 10 mm from the lower stage surface when load/unloading a substrate from the load lock body.

12. The load lock arrangement of claim 1, wherein the substrate stage includes a secondary stage for retaining an addition substrate.

13. The load lock arrangement of claim 1, wherein the load lock body further comprises an upper load lock chamber and a lower load lock chamber, the temperature control assembly being partially disposed within the upper load lock chamber.

14. The load lock arrangement of claim 13, further comprising an additional temperature control assembly partially disposed within the lower load lock chamber and coupled to a lower elevator for providing vertical displacement to the additional temperature control assembly.

15. A semiconductor processing system comprising:
a load lock arrangement including:
a load lock body;
a substrate stage housed within the load lock body;
a temperature control assembly including at a proximal end a temperature regulating head located within the load lock body and at a distal end a coupling connected to an elevator for raising and lowering the temperature regulating head, the distal end extending laterally through a side aperture located in a side face of the load lock body such that the distal end is located outside of the load lock body;
a flexible sealing mechanism connected between the side face of the load lock body and the temperature control assembly, the flexible sealing mechanism maintaining an internal environment within the load lock body during movement of the temperature regulating head;
a back-end transfer module connected to a rear face of the load lock body, the back-end transfer module coupling a process module to the load lock arrangement; and
an equipment front-end module connected to a front face of the load lock body, the equipment front-end module housing a front-end substrate transfer robot,
wherein the elevator is configured for lowering the temperature regulating head to allow the front-end substrate transfer robot to load/unload a substrate and raises the temperature regulating head to position the temperature regulating head proximate to the substrate stage to provide at least one of heating and cooling to a substrate seated on the substrate stage.

16. The semiconductor processing system of claim 15, wherein the load lock body further comprises an upper load lock chamber and a lower load lock chamber, the temperature control assembly being partially disposed within the upper load lock chamber.

17. The semiconductor processing system of claim 16, further comprising an additional temperature control assembly partially disposed within the lower load lock chamber and coupled to a lower elevator for providing vertical displacement to the additional temperature control assembly.

18. A method of processing a substrate comprising:
at a load lock body housing a substrate stage, the substrate stage including an upper stage surface and a lower stage surface, the upper stage surface configured for retaining a substrate at a retaining location within the load lock body;
lowering a vertical position of a temperature control assembly partially disposed within the load lock body to a load/unload position, the unload/load position being distal from the lower stage surface;
seating a process substrate on the upper stage surface at the retaining location; and
raising the vertical position of the temperature control assembly to a substrate temperature regulating position proximate to the lower stage surface to enable at least one of heating and cooling to the substrate positioned at the retaining location,
wherein lowering and raising of the temperature control assembly is implemented by an elevator coupled to a portion of the temperature control assembly extending outside of the load lock body through an aperture located in a side face of the load lock body.

19. The method of claim 18, wherein the temperature control assembly includes a temperature regulating head having an upper temperature regulating surface, wherein the upper temperature regulating surface is positioned at a distance greater than 10 mm from the lower stage surface when in the load/unloading position.

20. The method of claim 19, wherein the upper temperature regulating surface is positioned at a distance of less than 0.5 mm from the lower stage surface when located in the substrate temperature regulating position.
